(19) United States
(12) Patent Application Publication
(10) Pub. No.: US 2009/0212883 A1
(43) Pub. Date: Aug. 27, 2009

(54) FEEDTHROUGH FILTER AND ELECTRICAL MULTI-LAYER COMPONENT

(76) Inventors: Markus Albrecher, St. Stefan (AT); Günter Engel, Leibnitz (AT); Markus Ortner, Graz (AT)

Correspondence Address: FISH & RICHARDSON PC, P.O. BOX 1022, MINNEAPOLIS, MN, 55440-1022, US

(21) Appl. No.: 11/908,721

(22) PCT Filed: Mar. 14, 2006
(86) PCT No.: PCT/DE06/00451

§ 371 Date: Jul. 9, 2008

(30) Foreign Application Priority Data
Mar. 17, 2005 (DE) 102005012395.3

(51) Int. Cl. H03H 7/01; H01G 4/228; H01C 7/10

(52) U.S. Cl. 333/182; 361/306.3; 338/20

(57) ABSTRACT

A feedthrough filter includes a base plate having a first contact surface and a second contact surface. The first contact surface and the second contact surface are galvanically connected. The first contact surface is on an upper side of the base plate and the second contact surface is on an underside of the base plate. The base plate has an opening. An electrical feedthrough passes through the opening, is soldered to the second contact surface, and is not soldered to the first contact surface. A least one electrical component includes an external contact that is soldered to first contact surface.

### TECHNICAL FIELD

A feedthrough filter and an electrical multilayer component will be specified.

### BACKGROUND

A ceramic multilayer capacitor is known from the publication DE 101 36 545 A1. Another ceramic element as well as a method for its production is known from the publication DE 101 32 798 C1.

### SUMMARY

An electrical multilayer component is specified, comprising a base plate with flat external contacts on its first surface area and an active component area, arranged in the interior of the base plate, which does not overlap the external contacts on a projection plane onto which the active component area and the external contacts are orthogonally projected. The projection plane may be parallel to the base surface of the component. The specified multilayer component may be used in a feedthrough filter.

An arrangement comprising a base plate with a contact surface as well as an electrical component with a base body to be used in, for instance, a feedthrough filter, is additionally specified. An active component area is contained in the base body. An external electrode, which extends onto a side surface of the base body and onto a base surface (underside) of the base body, is arranged in the corner area of the base body. The area of the external electrode arranged on the base surface of the base body forms a contact area. The external electrode as well as the contact surface of the component are soldered to the connection surface of the base plate, i.e., tightly connected electrically as well as mechanically by a solder mass. A corner area—a crack-endangered area of the base body—which is a distance away from the active component area, is arranged between the edge of the contact surface facing away from the side surface and each point of the surface of the external electrode covered by the solder mass.

The crack-endangered area of the base body is thus arranged between surfaces that connect the first edge of the base body, facing away from the side surface, and the upper edge of the solder mass.

The external electrode located on the side as well as the contact area arranged on the surface area are wettable by a solder mass. The corner area of the base body, which is delimited essentially by mutually perpendicular surfaces, wettable with the solder mass, and a surface connecting the edges of these surfaces facing away from one another, is firmly connected to the base plate in the described arrangement, and viewed from the base plate, substantially incapable of vibrating. The remaining area of the base body not directly mounted on the base plate, on the other hand, is more capable of vibrating as viewed from the base plate. The border between the two areas just mentioned is susceptible to cracking. Since it can occur that the external electrode and/or the contact surface are not completely wetted with the solder mass, the entire corner area of the base body is in principle crack-endangered.

The multilayer component as well as embodiments of the component will be described below.

The base body has dielectric layers, which may be made of ceramic, between which internal electrodes are arranged that comprise opposed first and second internal electrodes of opposite polarity which are electrically connected to different external contacts. In one variant, the opposed first and second internal electrodes oppose one another in a transverse direction, i.e., they overlap. Opposed first and second internal electrodes can alternatively face one another in a longitudinal direction, wherein a first and a second internal electrode each lie in one plane and are arranged side by side.

Arranged on one surface of the base body, referred to in the present document as the peripheral surface, are external electrodes to which the internal electrodes are connected, and which are electrically connected to external contacts.

The base body has two base surfaces, upper side and lower side, each substantially parallel to a lateral plane, wherein at least one base surface is to be turned toward a circuit board when the component is mounted on the circuit board. The remaining surface of the base body is referred to as the peripheral surface. The peripheral surface of the base body comprises two opposing first side surfaces and two opposing second side surfaces. A first side surface is arranged perpendicular to the second side surfaces and vice versa.

The first base surface will be referred to below as the underside of the base body. This is not intended however, to be a restriction, since the upper side and the underside of the base body are interchangeable, e.g., by turning the component around. External contacts connected to the external electrodes, which do not overlap in the projection plane with the overlap area of the first and second internal electrodes, can also be placed on a second base surface of the base body. This is advantageous particularly if the component is intended for mounting (soldering) on two facing circuit boards between these circuit boards.

An active component area is understood to mean a volume in which the electric field strength is more than 5% of the maximum field strength between two oppositely charged internal electrodes. In a multilayer capacitor this is a component area that is defined in the lateral plane by mutually overlapping areas of the oppositely charged internal electrodes. A crack in the active area has an effect on the electrical properties of the feedthrough filter and, in the extreme case, can lead to a short circuit between the oppositely charged internal electrodes, whereas a crack in the base body outside the active area does not substantially impair the electrical properties of the feedthrough filter.

In a variant, an electrical multilayer component is specified with the base body having first and second internal electrodes arranged alternately one above the other, wherein the first internal electrodes are connected to a first external electrode and the second internal electrodes are connected to a second external electrode. The external electrodes are arranged on a peripheral surface of the base body and are each electrically connected to an external contact on a first base surface of the base body, wherein, in a lateral plane—projection plane—an arbitrarily selected first and a proximate second internal electrode have an overlap area that does not overlap the external electrodes.

In a cross section perpendicular to the internal electrodes and the external electrodes, the distance between the first external electrode and the edge facing it of an arbitrarily selected second internal electrode is greater than the cross sectional length in the same direction of the external contact connected to the first external electrode.

In an embodiment, the multilayer component is constructed as a capacitor with at least one capacitor element. In addition to capacitive elements, however, the multilayer component can also comprise additional elements, e.g., varistors. In the latter case, the dielectric layers are formed of a varistor ceramic. The first internal electrodes may form a first stack, and the second internal electrodes a second stack, the two stacks being arranged side by side and the active component area being arranged between the stacks.

The base body has dielectric layers, e.g., ceramic layers, between which metal layers with internal electrodes formed therein are arranged. Internal electrodes and dielectric layers arranged one above another form a stack.

In one variant, the ceramic can be a capacitor ceramic, COG, X7R, Z5U, Y5V, HQM. In an additional variant the ceramic can be a varistor ceramic containing a ZnO. The base body can have layers of different types of ceramics, e.g., at least one layer of capacitor ceramic and at least one additional layer of varistor ceramic. For instance, filters with an integrated varistor can be constructed as an ESD protector.

The first external electrodes connected to the first internal electrodes and the second external electrodes connected to the second internal electrodes can be arranged in one variant on different opposing side surfaces of the base body.

In one variant, the component can have several stacks arranged side by side, which may be electrically isolated from one another and are each realized as an independent component unit, for example, a capacitor element. In one variant, different component units can be contacted independently of one another via their own pair of external electrodes. The external electrodes are each electrically connected to an external contact of their own arranged on the underside of the base body, wherein for all stacks and all external electrodes, the first and the second internal electrodes of the stack have an overlap area in a projection plane that has no overlap with the external contacts.

In one variant, the first internal electrodes can be connected to two first external electrodes that are arranged on opposite first side surfaces of the base body. The second internal electrodes are connected in this case to two second external electrodes that are arranged on opposite second side surfaces of the base body.

Any desired ceramic materials appropriate for forming a capacitive component are conceivable as material for the base body. Metal layers with internal electrodes structured therein can contain any desired metals, metal alloys or combinations thereof.

In one variant, the external contact of the component is connected by solder to a contact surface of a circuit board. Due to different coefficients of expansion of the base body material (ceramic) and solder, a crack that starts at the inward-facing edge of the external contact and propagates itself upwards on a slant through the external electrode can arise in the base body in the event of temperature changes. Because the active volume of the component is set back from the peripheral areas of the component, it is not affected by the crack that is formed.

The specified component is thus distinguished by a high degree of reliability of its electrical properties in case a crack arises in the base body at the inward-facing edge of the external contact. In particular, a short circuit between the oppositely charged internal electrodes in the event of a crack formation can be prevented with the described measures.

The described multilayer component is usable, in particular, in a feedthrough filter explained below.

Also specified is a feedthrough filter having a base plate. The base plate has a first contact surface arranged on its upper side and a second contact surface arranged on its underside that are galvanically connected to one another. An electrical feedthrough (lead), which is soldered to the second contact surface but not to the first one, is led through the base plate. At least one electrical component whose first external component is soldered to the first contact surface is arranged on the base plate. In a variant, several electrical components are arranged on the base plate.

The upper side and the underside of the base plate can be interchanged with one another by turning the base plate over.

An opening having a metallized internal peripheral surface and suitable for accommodating the electrical feedthrough may be formed in the base plate. The inside diameter of the opening may be matched to the outside diameter of the feedthrough. The first and the second contact surfaces are galvanically connected to one another by this opening.

The solder point between the base plate and the electrical component is relieved with regard to mechanical stresses, generally tensile forces, that can be transferred through the feedthrough by virtue of the fact that the solder point between the feedthrough and the base plate is arranged on the other side of the base plate. Thus, a mechanical decoupling between the electrical feedthrough and the electrical component can be achieved with the described measure.

The base plate can, for instance, be formed from a conventional copper-coated circuit board (PCB, printed circuit board), e.g., for forming contact surfaces, and made from, for instance, FR4 or an organic material suitable for high-frequency applications.

The feedthrough may be insulated from the housing. The feedthrough serves for contacting the electrical component, which is generally housed and/or encapsulated by a molding compound. The feedthrough may be embedded in the molding compound, which has the advantage that the feedthrough is therefore better fixed in the component. In one variant, the housing comprises a cover that seals tightly to the base plate. The housing may be electrically conductive and can be a metal housing. The housing may be galvanically connected to at least one printed conductor of the base plate. This printed conductor can be arranged in the cavity, i.e., on the upper side of the base plate, or alternatively, on the underside of the base plate.

Mounting devices, such as mounting brackets with holes for mounting the feedthrough filter on a carrier, can be provided on the housing

The housing is advantageous for the functioning of the feedthrough filter, but not absolutely necessary, if, for example, the feedthrough filter is to be integrated into an electrical module, which may be furnished with a cover. It is therefore possible to forego the housing of the feedthrough filter.

The base plate can be a component of the housing. A cavity in which the electrical component is arranged is formed between the housing and the base plate. The cavity can be filled with a molding compound which on the one hand encapsulates the electrical component, and on the other fixes the electrical feedthrough in the housing.

In one variant the cavity is filled with air, in which case the electrical component is not encapsulated.

The electrical component integrated in the feedthrough filter may be an SMD component, i.e., a surface mounted device.

The feedthrough is electrically connected to the electrical component. The feedthrough can be flexible. In one variant, it can be a composite of several stranded conductors. Alternatively, the feedthrough can be a bare wire. Depending on the design, the wire can be flexible or rigid.

In order to reduce the undesired effect of tensile forces or flexural forces on the feedthrough filter, it is advantageous to center the hole provided for the feedthrough in the base plate. The feedthrough is thus may be arranged in the center of the base plate.

The feedthrough filter is formed in one variant as a feedthrough capacitor with at least one, or at least two, housed multilayer capacitors. The multilayer capacitors may be connected to one another in parallel. Multilayer capacitors have the advantage that they have high capacitance values with small dimensions.

The feedthrough filter can be a filter in general. In addition to multilayer capacitors, the feedthrough filter can also contain additional components, e.g., at least one inductive component or one varistor, such as a multilayer varistor. The additional components may be arranged on the base plate.

A symmetrical construction of the feedthrough filter, for example with two identical multilayer capacitors, has advantages.

The feedthrough filter is suitable for removing noise from a power supply line or signal line of a downstream device. In comparison to a feedthrough filter with tubular capacitors, the feedthrough filter with ceramic multilayer capacitors is distinguished by a smaller space requirement for a given capacitance.

A second external contact of the electrical component may be soldered to a third contact surface on the upper side of the base plate. In one variant, the third contact surface is connected by a plated through-hole to a fourth contact surface arranged on the underside of the base plate.

The electrical multilayer component and the feedthrough filter will be explained below on the basis of schematic figures not drawn to scale.

### DESCRIPTION OF THE DRAWINGS

FIG. 1A, a perspective view of a multilayer component according to a first embodiment;

FIGS. 1B and 1C, respectively, cross sections of the multilayer component according to FIG. 1A, perpendicular to the internal electrodes;

FIG. 1D, a view of overlapping internal electrodes and external contacts of the component according to FIGS. 1A-1C in a lateral projection plane;

FIG. 2A, a perspective view of a multilayer component according to a second embodiment;

FIGS. 2B and 2C, respectively, cross sections of the multilayer component according to FIG. 2A, perpendicular to the internal electrodes;

FIG. 2D, a view of overlapping internal electrodes and external contacts of the component according to FIGS. 2A-2C in a lateral projection plane;

FIGS. 3A and 3B, respectively, a cross section of the multilayer component according to FIG. 2A, that is mounted on a circuit board and in which cracks have formed;

FIG. 4A, a perspective view of a multilayer component according to a third embodiment;

FIGS. 4B and 4C, respectively, a cross section of the multilayer component according to FIG. 4A, perpendicular to the internal electrodes;

FIG. 5, in cross section, a feedthrough filter with multilayer capacitors formed on a base plate;

FIG. 6, in cross section, a feedthrough filter with multilayer capacitors arranged between two base plates;

FIG. 7A, a view of the base plate according to FIG. 5 from the bottom;

FIG. 7B, a view of the base plate according to FIG. 5 from above.

### DETAILED DESCRIPTION

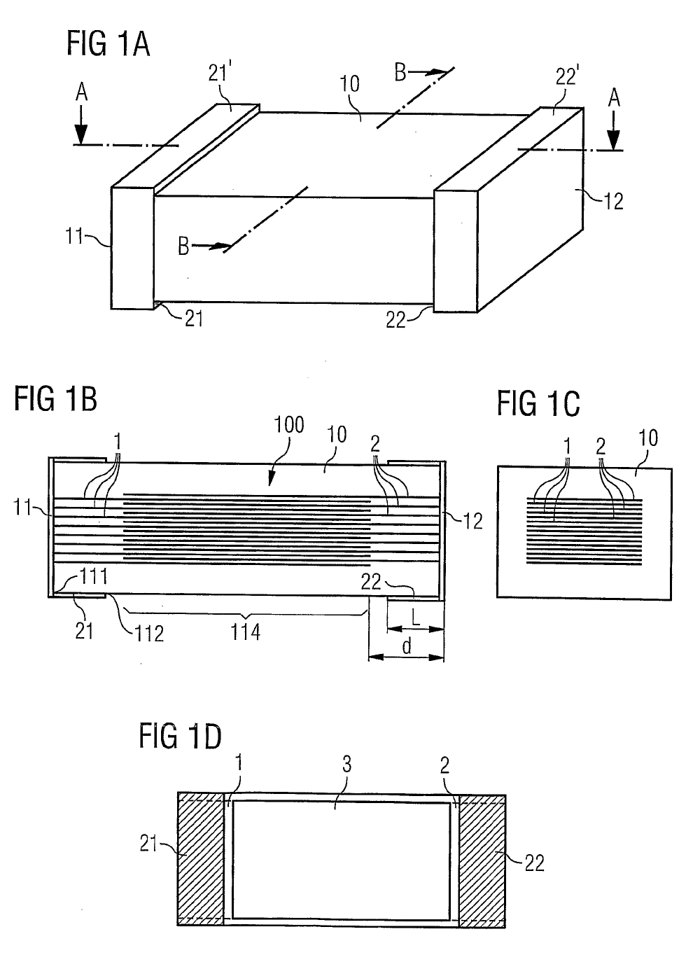

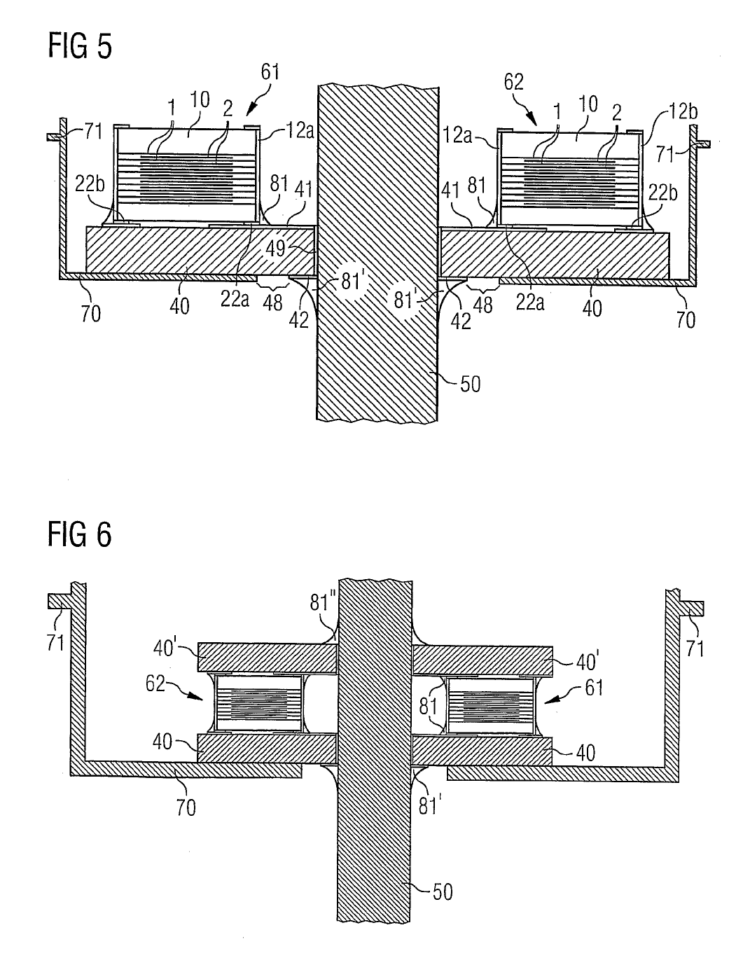

In FIG. 1A, a first multilayer component with a base body 10 and external electrodes 11, 12 is shown. External electrodes 11, 12 are arranged on opposite side surfaces of base body 10, and extend past the edges 111 of the respective side surface. A part of external electrode 11, 12 arranged on the underside of base body 10 forms a respective external contact 21, 22. A part of external electrode 11, 12 arranged on the upper side of base body 10 forms a respective external contact 21′, 22′, which can be used, for example, for connection to an upper base plate 40′ shown in FIG. 6. External contact 21 has an edge 112, facing away from the side surface, at which a crack can begin during connection of the component to a base plate 40.

In FIG. 1B, a section of this component along line AA is shown, and in FIG. 1C, a section along line BB.

The first internal electrodes 1 connected to first external electrode 11 and the second internal electrodes 2 connected to second external electrode 12 interpenetrate one another. Together with dielectric layers arranged between them, the parts of internal electrodes 1, 2 arranged one above the other form a stack 100, which corresponds substantially to an active component area 114.

The distance d measured in the longitudinal direction x between second external electrode 12 and the edges facing it of first internal electrodes 1 is greater than the length measured in this direction of external contacts 22 associated with external electrode 12. This also applies to first external electrode 11, external contact 21 and second internal electrodes 2. In a projection plane shown in FIG. 1D therefore, the surfaces of external contacts 21, 22 are a distance away from the overlap area 3 of first and second internal electrodes 1, 2.

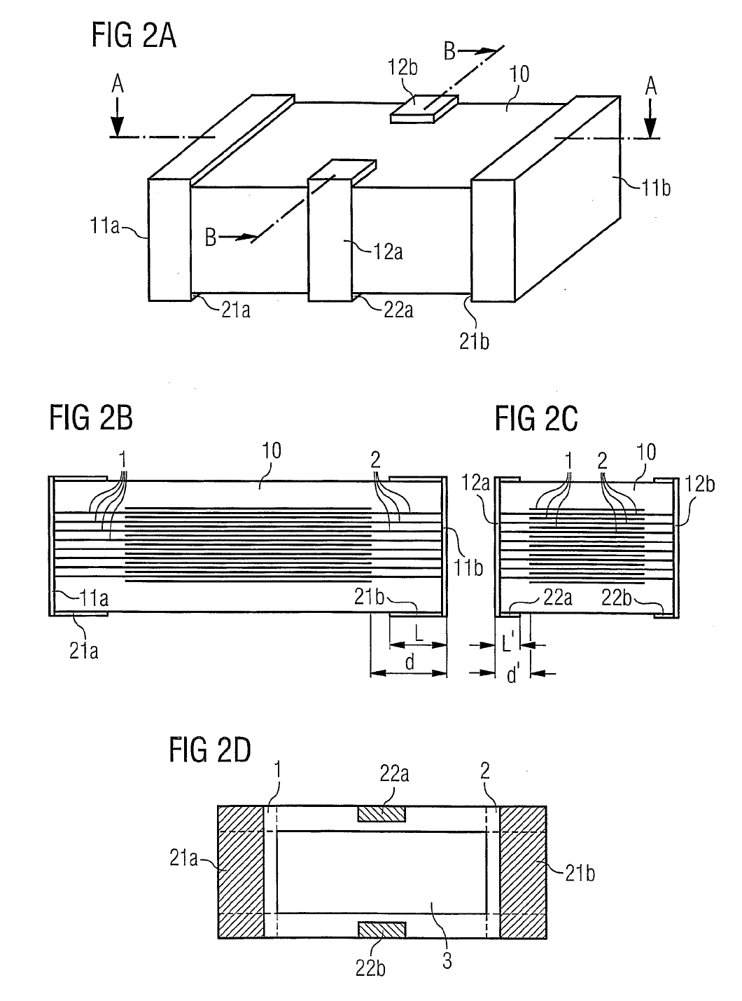

A second multilayer component with two first external electrodes 11a, 11b and two second external electrodes 12a, 12b is shown in FIGS. 2A-2D. In this variant, first internal electrodes 1 are connected to first external electrodes 11a, 11b on opposite first side surfaces of base body 10. Second internal electrodes 2 are connected to second external electrodes 12a, 12b on opposite second side surfaces of base body 10.

Second internal electrodes 2 are dimensioned in the longitudinal direction x such that they are separated from first external electrodes 11a, 11b by a larger amount d than the cross sectional length L of external contacts 21a, 21b, respectively. First internal electrodes 1 are dimensioned such that they are separated from second external electrodes 12a, 12b by a larger amount d′ than the cross sectional length L′ of external contacts 22a, 22b, respectively.

The projection of the underside of the component as well as of the first and second internal electrodes 1, 2 onto a lateral projection plane is shown in FIG. 2D. Overlap area 3 of first and second internal electrodes 1, 2 is a distance away from external contacts 21a, 21b, 22a, 22b.

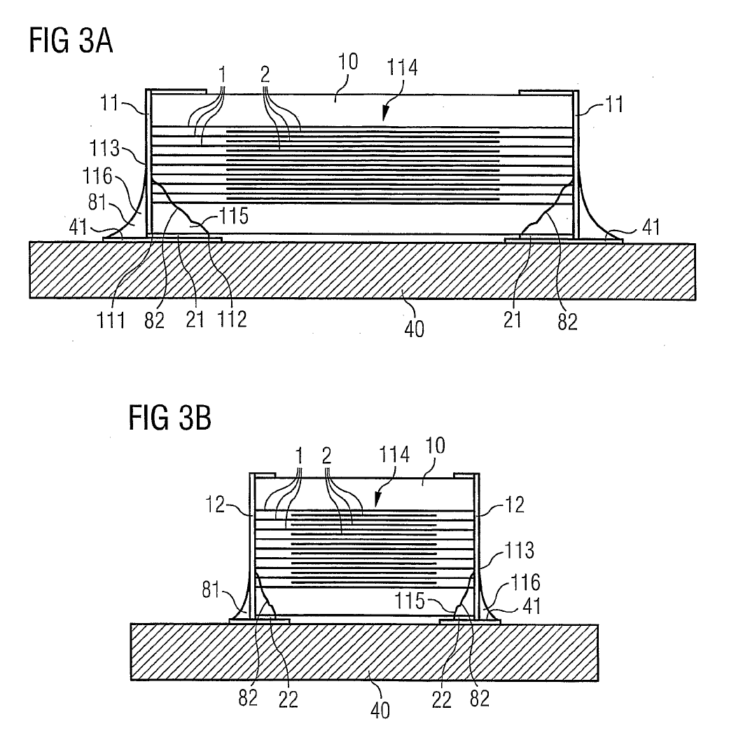

The component according to a second embodiment, which is mounted by f- solder 81 on contact surfaces 41 of a base plate 40 (e.g., a circuit board) is shown in FIGS. 3A, 3B. A crack 82 that connects the boundaries of the solder point in the longitudinal direction and in the vertical direction to one another has formed in base body 10. Crack 82 begins at the inward-directed edge of external contact 21, 22, because this edge defines the boundary between mounted parts and a part of base body 10 that can vibrate.

A crack-endangered corner area of base body 10 is arranged between edge 111 between the side surface and the underside of the base body, edge 112 of external contact 21 facing away from the side surface, and upper edge 113 of solder mass 116. Active component area 114 is a distance away from this corner area.

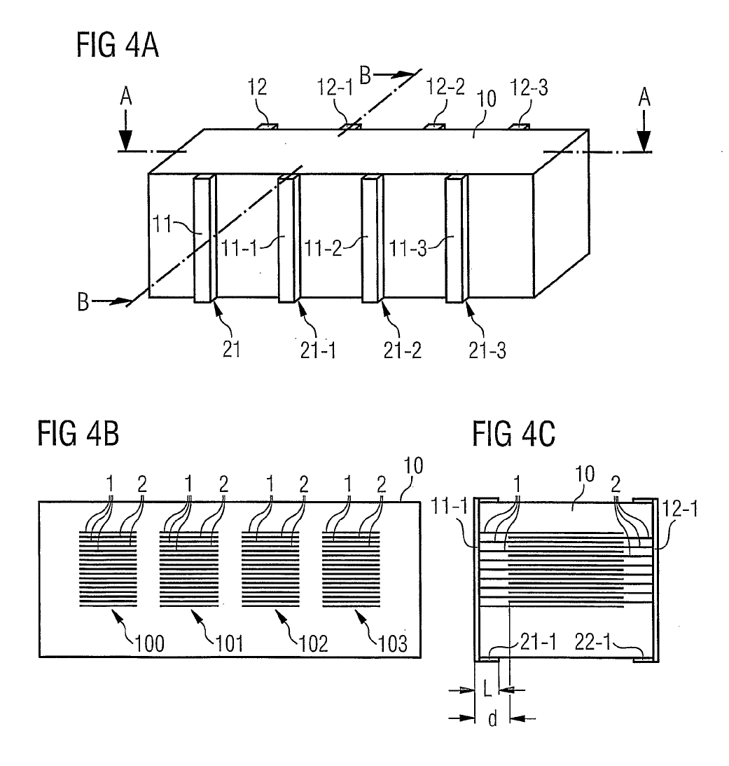

An embodiment of the multilayer component with several independent functional units is shown in FIGS. 4A-4C. The functional units are each formed by a stack 100, 101, 102, 103 of dielectric layers and mutually overlapping first and second internal electrodes 1, 2. Each stack 100, 101, 102, 103 is connected to a pair of external electrodes 11, 12; 11-1, 12-1; 11-2, 12-2; 11-3, 12-3. The external electrodes have external contacts 21, 22; 21-1, 22-1; 21-2, 22-2; 21-3, 22-3. The stacks are electrically isolated from one another. Each stack is substantially formed like the stack 100 already explained in FIGS. 1A-1D.

The multilayer components shown in FIGS. 1A-4C are surface-mountable multilayer capacitors. In another variant however the multilayer components can be multilayer varistors.

FIG. 5 schematically shows a part of the fundamental structure of a feedthrough filter with two electrical components 61, 62, which are constructed as multilayer capacitors. The multilayer capacitors can have different capacitance values in one variant. In another variant, the multilayer capacitors can have identical capacitance values.

Components 61, 62 are arranged on the upper side of a base plate 40 and tightly connected to contact surfaces 41, 43 of this base plate by solder 81. Components 61, 62 here are multilayer components according to the second embodiment (FIGS. 2A-2D). Components 61, 62 can also have a different structure, for instance, one according to the first or the second embodiment.

It is advantageous to place the two components 61, 62 on one side of base plate 40.

First and third contact surfaces 41, 43 are arranged on the upper side of base plate 40. A second contact surface 42 is arranged on the underside of base plate 40. An opening 49, whose inside surface is metallized, is provided in base plate 40. Thus a vertical electrical connection of first and second contact surfaces 41, 42 is assured.

Opening 49 is arranged in base plate 40. An electrical feedthrough 50—in this variant a bare wire—is passed through opening 49. The cross section of feedthrough 50 may be form-fit to the cross section of opening 49. Feedthrough 50 is soldered to second contact area 42 on the underside of the base plate.

Due to their placement on different sides of base plate 40, solder joints 81′ between base plate 40 and feedthrough 50 are substantially decoupled mechanically from solder joint 81 between base plate 40 and components 61, 62.

The feedthrough filter can contain more than only two components. In one variant, four multilayer capacitors with capacitance values differing from one another are mounted on base plate 40. All components may be arranged only on one side of the base plate. In one variant, both sides of the base plate are equipped with such components.

The surface area of the base plate may be less than 100 mm² and is typically 80 mm². The base plate in one variant can comprise a thin, flexible film coated with a solderable conductive layer, e.g., a metal layer.

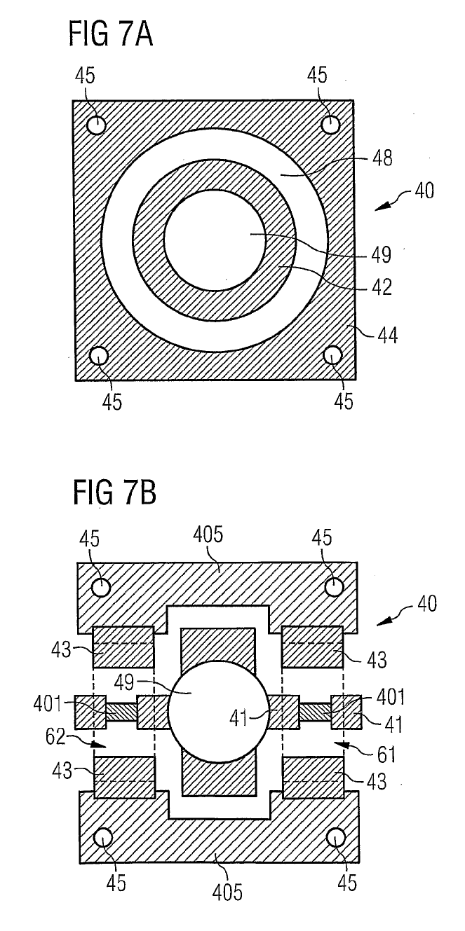

An example of a base plate 40 is shown in FIGS. 7A, 7B.

Base plate 40 is arranged in a housing 70 which may be made of metal. Mounting parts 71, formed as elevations in this variant, are provided on the housing walls for mounting the component on an external carrier. The part of the housing facing the underside of base plate 40 can be tightly connected to fourth contact area 44 of base plate 40 by, for instance, a solder mass, not shown here.

FIG. 6 shows a feedthrough filter with multilayer capacitors 61, 62 arranged between two base plates 40, 40′. The external electrodes of multilayer capacitors 61, 62 are respectively tightly connected to the two base plates 40, 40′ by a solder mass 81. As in FIG. 5, feedthrough 50 is tightly connected to lower base plate 40 by solder mass 81′ and to upper base plate 40′ by solder mass 81″.

For upper base plate 40′ as well, feedthrough 50 and multilayer capacitors 61, 62 are therefore attached on different sides of base plate 40′.

FIG. 7A shows the view of the underside of base plate 40 from FIG. 5, and FIG. 7B the view of the upper side, which is laid out for a component 61, 62 in accordance with, whose external contacts 21a, 21b, 22a, 22b are arranged as in the variant shown in FIG. 2A. The position of component 61, 62 on base plate 40 is indicated with a broken line.

On the underside of base plate 40 a fourth contact surface 44 is provided, which is electrically connected by plated through-holes 45 to two printed conductors 405 located on the upper side of the base plate. Apart from its areas provided as third contact surfaces 43, printed conductor 405 may be passivated, i.e., covered by an insulating layer not shown here, made of a halogen-free material, for example. Third contact areas 43 are soldered to external contacts 21a, 21b of the component shown in FIGS. 2A-2D. Contact areas 41 are soldered to external contacts 22a, 22b of the aforementioned component. Two contact areas 41 provided for a component 61 or 62 are electrically connected to one another by, e.g., a passivated electrical connection 401.

An insulating area 48 is arranged between second contact area 42 and fourth contact area 44.

The base plate 40 shown in FIGS. 7A, 7B is symmetrically constructed relative to a transversal or longitudinal axis passing through the center of the base plate. The center of opening 49 provided for feedthrough 50 coincides here with the center of the base plate.

In addition to the printed conductors shown, printed conductors having additional contact surfaces, which are connected to additional components such as multilayer varistors based on a ZnO-containing ceramic, can be provided on the base plate 40.

The following materials are possible as capacitor ceramic: COG, X7R, Z5U, Y5V, HQM.

The feedthrough filters and multilayer components described here are not limited to the embodiments shown in the figures or the number of components represented.

1. A feedthrough filter comprising:
a base plate comprising:
a first contact surface; and
a second contact surface;
the first contact surface and the second contact surface being galvanically connected, the first contact surface being on an upper side of the base plate and the second contact surface being on an underside of the base plate; and
the base plate having an opening;
an electrical feedthrough that passes through the opening, that is soldered to the second contact surface, and that is not soldered to the first contact surface; and
at least one electrical component comprising an external contact that is soldered to first contact surface.

2. The feedthrough filter of claim 1, wherein the opening is in a center area of the base plate.

3. The feedthrough filter of claim 1, wherein the electrical feedthrough comprises at least one wire.

4. The feedthrough filter of claim 1, wherein the opening comprises a metallized inner surface that galvanically connects the first contact surface and the second contact surface.

5. The feedthrough filter of claim 1, wherein the at least one electrical component comprises as a ceramic multilayer capacitor.

6. The feedthrough filter of claim 5, wherein the ceramic multilayer capacitor is surface-mountable.

7. The feedthrough filter of claim 6, wherein the ceramic multilayer capacitor comprises a base body comprising flat external contacts on a base surface of the base body.

8. The feedthrough filter of claim 7, wherein the base body comprises an active component area in an interior of the base body, and wherein, in an orthogonal projection onto the base surface, the active component area does not overlap the flat external contacts.

9. The feedthrough filter of claim 1, wherein the at least one electrical component comprises an additional external contact soldered to a third contact surface on the upper side of the base plate.

10. The feedthrough filter of claim 9, wherein the third contact surface is galvanically connected, via a plated through-hole, to a fourth contact surface on the underside of base plate.

11. The feedthrough filter of claim 1, further comprising a housing connected to the base plate, wherein a cavity between the housing and the base plate contains the at least one electrical component.

12. The feedthrough filter of claim 11, wherein the housing comprises metal.

13. The feedthrough filter of claim 11, wherein the housing comprises mounting devices for mounting the feedthrough filter on a carrier.

14. The feedthrough filter of claim 11, wherein the cavity comprises an insulating molding compound.

15. The feedthrough filter of claim 14, wherein the electrical feedthrough is held in place by the molding compound.

16. The feedthrough filter of claim 1 that comprises two multilayer capacitors connected in parallel.

17. An electrical multilayer component comprising:
a base body comprising:
external contacts on a first base surface; and
an active component region in an interior of the base body, which in an orthogonal projection onto the base surface, does not overlap the external contacts.

18. The electrical multilayer component of claim 17, wherein the base body comprises dielectric layers and internal electrodes among the dielectric layers.

19. The electrical multilayer component of claim 18, wherein the internal electrodes comprise first internal electrodes and second internal electrodes opposite one another and electrically connected to different external contacts.

20. The electrical multilayer component of claim 18, further comprising external electrodes connected to the external contacts, the external electrodes being on a peripheral surface of base body.

21. The electrical multilayer component of claim 18, wherein electrical field strength in the active component region is more than 5% of a maximum electrical field strength between opposing oppositely-charged internal electrodes.

22. The electrical multilayer component of claim 19, wherein the first and second internal electrodes are arranged alternately one above the other; and
wherein, in an orthogonal projection onto the base surface, the first and second internal electrodes have an overlap area that does not overlap the external contacts.

23. The electrical multilayer component of claim 18, wherein the dielectric layers comprise a capacitor ceramic.

24. The electrical multilayer component of claim 18, wherein the dielectric layers comprise a varistor ceramic.

25. The electrical multilayer component of claim 20, wherein different external electrodes are on opposite side surfaces of the base body.

26. The electrical multilayer component of claim 20, wherein first internal electrodes are connected to two first external electrodes that are on opposite first side surfaces of the base body, and
wherein second internal electrodes are connected to two second external electrodes that are on opposite second side surfaces of the base body.

27. The electrical multilayer component of claim 18, wherein the base body comprises:
a first stack of dielectric layers;
a second stack of dielectric layers;
first and second internal electrodes among the first stack of dielectric layers; and
second internal electrodes among the second stack of dielectric layers.

28. The electrical multilayer component of claim 27, wherein the first and second stacks of dielectric layers are alongside each other;
wherein each stack of dielectric layers is electrically connected to a pair of external electrodes, each external electrode being connected to an external contact on an underside of the base body;
wherein for all stacks of dielectric layers and all external contacts, in an orthogonal projection onto the base surface, first and second internal electrodes of a stack of dielectric layers have an overlap area that does not overlap external contacts.

29. The feedthrough filter of claim 1, wherein the at least one electrical component comprises:
a base body comprising:
external contacts on a first base surface; and
an active component region in an interior of the base body, which in an orthogonal projection onto the base surface, does not overlap the external contacts.

30. An arrangement comprising:
a base plate comprising a connection surface;
an electrical component comprising a base body and an active component area;
an external electrode that extends to a base surface and to a side surface of the base body, the external electrode being in a corner area of the base body, wherein an area of the external electrode on the base surface of base body defines a contact surface;
wherein the external electrode is soldered to the connection surface via a solder mass; and
wherein an area between an edge of a contact surface facing away from the side surface and each point of a surface of the external electrode covered by the solder mass is a distance away from the active component area.

31. The arrangement of claim 30, wherein the electrical component comprises:
a base body comprising:
external contacts on a first base surface; and
an active component region in an interior of the base body, which in an orthogonal projection onto the base surface, does not overlap the external contacts.

32. The arrangement of claim 30, wherein the active component area is connected to an external electrode.

33. The feedthrough filter of claim 1, further comprising:
an additional base plate comprising a third contact surface and a fourth contact surface, the third contact surface being on an underside of the additional base plate and the fourth contact surface being on an upper side of the additional base plate, the third contact surface and the fourth contact surface being galvanically connected;
wherein the additional base plate comprises an opening through which the electrical feedthrough passes, the electrical feedthrough being soldered to the fourth contact surface but not to the third contact surface; and
wherein an external contact of the at least one electrical component is soldered to the third contact surface.
